(19) United States
(12) Patent Application Publication
(10) Pub. No.: US 2019/0348589 A1
(43) Pub. Date: Nov. 14, 2019

(54) LIGHT-EMITTING DIODE STRUCTURE

(71) Applicants: Mutual-Pak Technology Co., Ltd., Taoyuan County (TW); HSN Materials Co., Ltd., Taipei City (TW)

(72) Inventors: Lu-Chen HWAN, Taoyuan County (TW); Kun-Chui LEE, Taipei City (TW)

(21) Appl. No.: 16/394,532

(22) Filed: Apr. 25, 2019

(30) Foreign Application Priority Data
May 9, 2018 (TW) 107115805

(51) Int. Cl. H01L 33/64; H01L 25/075; H01L 33/62; H01L 33/50

(52) U.S. Cl. CPC H01L 33/64; H01L 25/0753; H01L 2225/107; H01L 33/50; H01L 2225/06513; H01L 33/62

(57) ABSTRACT

The present invention relates to a light-emitting diode (LED) structure, comprising a flexible substrate and one or a plurality of chip-scale package (CSP) LED chips. The flexible substrate includes a metal layer as the core, and the metal layer is coated with a ceramic insulating layer. The flexible substrate is provided with a plurality of electrodes. The CSP LED chips are provided on the flexible substrate, with the electrical connection units of each CSP LED chip electrically connected to the corresponding electrodes on the flexible substrate respectively.

### BACKGROUND OF THE INVENTION

### 1. Technical Field

The present invention relates to a light-emitting diode (LED) structure and more particularly to one for use in an LED lightbulb or as an LED filament.

### 2. Description of Related Art

LEDs have been used extensively in lighting devices and various industries due to their advantageous features, namely low power consumption, high brightness, low voltage, ease of matching with integrated circuits, a simple driving mechanism, and long service lives.

Recently, the chips in LEDs have progressed from the conventional wire-bonded ones to flip chips and those configured for chip-scale packaging (CSP), the objective being to downsize packaged LEDs.

A conventional wire-bonded LED chip requires a wire bonding process before packaging, wherein the wire bonding process uses a wire to electrically connect each of the n-electrode and p-electrode of the chip to the corresponding electrode on a heat-dissipating plate. An LED flip chip, on the other hand, is constructed with a heat-dissipating plate on which solder bumps are provided as electrodes, and each of the n- and p-electrodes of the chip is electrically connected to the corresponding solder bump without using wires, bond pads, or other wire-bonding elements, thereby providing improvement over the complicated manufacturing process of wire-bonded LED chips.

The more recently developed chip-scale package LED (or CSP LED for short) has its heat-dissipating plate (which is similar to that of an LED flip chip) removed during manufacture and its n- and p-electrodes disposed directly on a substrate to reduce the thickness of the package, which results in certain desirable electrical properties as well (e.g., low inductance and low capacitance, thanks to the relatively short electrical conduction path).

### BRIEF SUMMARY OF THE INVENTION

While a CSP LED has an advantageously small volume and good electrical properties, it dissipates heat poorly because of no heat-dissipating plate (e.g., conventional LED package has a ceramic heat-dissipating plate connected to the bottom of the n- and p-electrodes of the chip in the first place) during the packaging process and the chip is disposed directly on a metal core printed circuit board (MCPCB) and then packaged for use. More specifically, the heat flux in the CSP LED can be dissipated only through the soldering surface between each of the n- and p-electrode bumps and the MCPCB, i.e., without the assistance of the heat-dissipating plate that could otherwise dissipate heat evenly as in the case of a wire-bonded chip or a flip chip. As a result, the heat of the CSP LED tends to be overly concentrated, which hinders efficient dissipation and may eventually reduce the brightness and service life of the CSP LED after long-term use.

As above, the objective of the present invention is to provide a LED structure, including a flexible substrate and one or a plurality of chip-scale package LED (or one or a plurality of CSP LED chips for short). The flexible substrate includes a metal layer as the core, and the metal layer is coated with a ceramic insulating layer. The flexible substrate is provided with a plurality of electrodes. The CSP LED chips are provided on the flexible substrate, with the electrical connection units of each CSP LED chip electrically connected to the corresponding electrodes on the flexible substrate respectively. The flexible substrate may further have a plurality of through holes and an electrical conduction unit in each of the through hole.

Another objective of the present invention is to provide a LED structure, including a flexible substrate and one or a plurality of CSP LED chips. The flexible substrate includes a metal layer as the core, and the metal layer is coated with a ceramic insulating layer. The flexible substrate has a plurality of through holes and an electrical conduction unit in each through hole. The CSP LED chips are provided on the flexible substrate, with the electrical connection units of each CSP LED chip electrically connected to the corresponding electrical conduction units on the flexible substrate respectively.

Furthermore, the ceramic insulating layer has a thickness of 10 μm˜400 μm.

Furthermore, the flexible substrate includes at least one cup structure, and each CSP LED chip is provided in a corresponding of the cup structure.

Furthermore, the LED structure includes one or a plurality of fluorescent layers formed on the flexible substrate to cover the CSP LED chips respectively.

Comparing to the conventional LED structure, the LED structure of the present invention has the following advantages.

1. The LED structure disclosed herein includes a flexible substrate and a plurality of CSP LED. The flexible substrate includes a core metal layer coated with a ceramic insulating layer. The CSP LED chip is provided on the flexible substrate. As the metal layer and the ceramic insulating layer have good heat dissipation properties, the resulting CSP LED is free of the drawbacks of its conventional counterparts, such as an overly concentrated heat flux and the incapability to dissipate heat evenly.

2. The flexible substrate of the LED structure disclosed herein includes the core metal layer and the ceramic insulating layer coating and is therefore different from the entirely ceramic, and hence costlier, substrate of a conventional LED structure. In addition, the flexibility of the core metal layer provides better mechanical strength and allows variation of the exterior design of the LED structure disclosed herein, thereby increasing industrial applicability of the present invention. For example, the LED structure disclosed herein can be bent for use as an LED filament.

3. The CSP LED chip in the LED structure disclosed herein can be disposed directly on the flexible substrate using surface mount technology (SMT) equipment, without requiring a vacuum clean room or a die bonding machine (both being expensive) as does an LED flip chip. The LED structure, therefore, features relatively low production cost.

### BRIEF DESCRIPTION OF THE SEVERAL VIEWS OF THE DRAWINGS

FIG. 1 is the sectional view (I) of the LED structure according to the first embodiment of the present invention.

FIG. 2 is the sectional view (II) of the LED structure according to the first embodiment of the present invention.

FIG. 3 is the sectional view of the CSP LED chips of the present invention.

FIG. 4 is the sectional view (I) of the LED structure according to the second embodiment of the present invention.

FIG. 5 is the sectional view (II) of the LED structure according to the second embodiment of the present invention.

FIG. 6 is the sectional view (III) of the LED structure according to the second embodiment of the present invention.

FIG. 7 is the sectional view (I) of the LED structure according to the third embodiment of the present invention.

FIG. 8 is the sectional view (II) of the LED structure according to the third embodiment of the present invention.

FIG. 9 is the sectional view (III) of the LED structure according to the third embodiment of the present invention.

### DETAILED DESCRIPTION OF THE INVENTION

The following description is the essential techniques of the present invention that can be understood by a person having ordinary skill in the art. And without inconsistence of the scope or spirits of the present invention, the changes and modification can be done for different condition and application. Thus, the implement with changes and modification of the present invention still fall within the claims of the present invention.

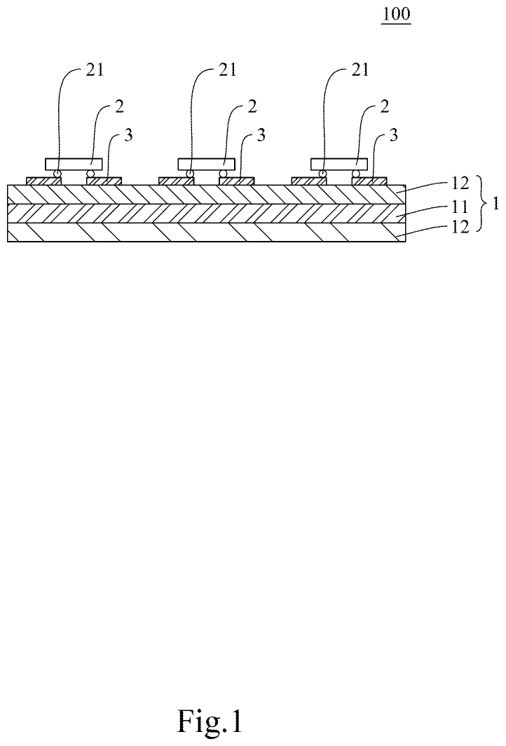

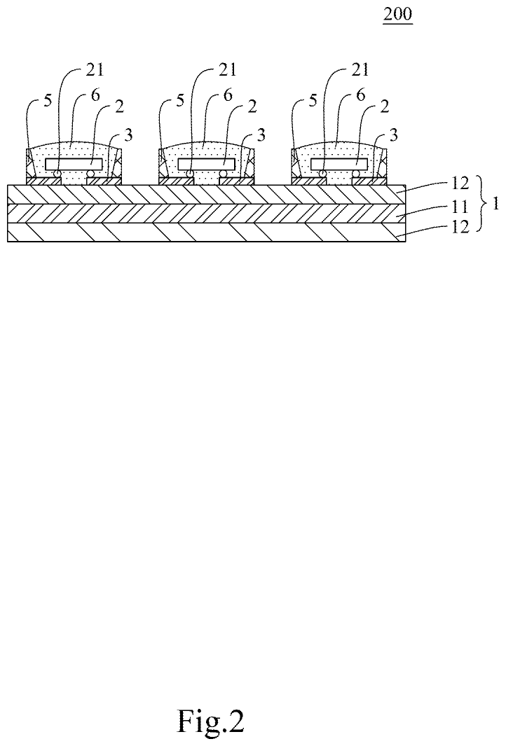

FIG. 1 and FIG. 2 show two LED structures according to the first embodiment of the present invention in sectional view.

In this embodiment, referring first to FIG. 1, the LED structure 100 includes a flexible substrate 1 and one or a plurality of CSP LED chips 2. The flexible substrate 1 includes a metal layer 11 as the core, and the metal layer 11 is coated with a ceramic insulating layer 12. The flexible substrate 1 is provided with a plurality of electrodes 3. The CSP LED chips 2 are provided on the flexible substrate 1, with the electrical connection units 21 of each CSP LED chip 2 electrically connected to the corresponding electrodes 3 on the flexible substrate 1 respectively.

The flexible substrate of the LED structure in this embodiment may further include at least one cup structure and at least one fluorescent layer as needed. Referring to FIG. 2, each CSP LED chip 2 of the LED structure 200 is provided in a corresponding cup structure 5, and a plurality of fluorescent layers 6 are formed on the flexible substrate 1 to cover the CSP LED chips 2 respectively.

In this embodiment, the metal layer 11 may be copper, aluminum, a copper alloy, or an aluminum alloy. The copper alloy may be, but is not limed to, a copper-zinc alloy, a copper-tin alloy, a copper-aluminum alloy, a copper-silicon alloy, or a copper-nickel alloy. The aluminum alloy may be, but is not limited to, an aluminum-silicon alloy, an aluminum-magnesium-silicon alloy, an aluminum-copper alloy, an aluminum-magnesium alloy, an aluminum-manganese alloy, an aluminum-zinc alloy, or an aluminum-lithium alloy. The metal layer 11 is preferably copper or aluminum.

In this embodiment, the ceramic insulating layer 12 may be any common ceramic material, including but not limited to various metal oxides, carbides, nitrides, borides, silicides, and combinations thereof, some examples of which are silicon carbide (SiC), silicon nitride (Si₃N₄), aluminum nitride (AlN), aluminum oxide (Al₂O₃), titanium carbide (TiC), titanium boride (TiB₂), and boron carbide (B₄C). Preferably, the ceramic insulating layer 12 is aluminum oxide (Al₂O₃), silicon nitride (Si₃N₄), or aluminum nitride (AlN), the three of which have good thermal conductivity and low coefficients of expansion. The ceramic insulating layer 12 may be formed by any common ceramic-metal composite forming method, including but not limited to coating, anodizing, micro-arc oxidation, plasma electrolytic oxidation, magnetron sputtering, and a sol-gel process. The ceramic insulating layer 12 has a thickness of 10 μm˜900 μm, preferably 10 μm˜400 μm, more preferably 30 μm˜50 μm. A ceramic insulating layer 12 whose thickness falls into any of the foregoing ranges is not prone to embrittlement but flexible and can withstand the stamping force applied during the substrate machining process. The ceramic insulating layer 12 may also be rendered reflective by a mirror surface finish to increase the brightness of the LED structure.

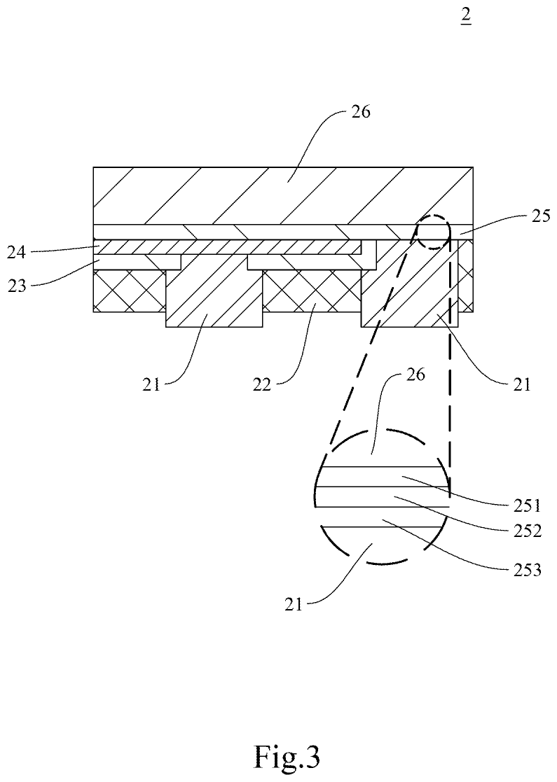

In this embodiment, the CSP LED chips 2 may be any LED chips that are configured for chip-scale packaging, such as but not limited to those configured to form carrier-type CSPs, tape-type CSPs, or resin-sealed CSPs. Preferably, the CSP LED chips 2 have the configuration shown in FIG. 3, i.e., including a substrate 26, a first semiconductor layer 251, a light-emitting layer 252, a second semiconductor layer 253, a passivation layer 24, a plurality of extension contacts 23, a protective layer 22, and at least one electrical connection unit 21. The second semiconductor layer 253 and the light-emitting layer 252 have a plurality of vias (not shown), whose diameters range from 3 μm to 10 μm and which maintain electrical contact between most of the light-emitting layer 252 and of the second semiconductor layer 253 such that the CSP LED chip 2 does not have a non-light-emitting zone and can output light of enhanced intensity as compared with a conventional wire-bonded LED (whose light-emitting zone is partially blocked by the electrodes) and a conventional LED flip chip (which has a non-light-emitting zone constituting typically 20%-30% of the entire die and thus limiting the intensity of output light). The substrate 26 may be a glass substrate, a sapphire substrate, a SiC substrate, a gallium phosphide (GaP) substrate, a gallium arsenide phosphide (GaAsP) substrate, a zinc selenide (ZnSe) substrate, a zinc sulfide (ZnS) substrate, or a zinc sulfide selenide (ZnSSe) substrate. The semiconductor layer and light-emitting layer assembly 25 is so structured that the light-emitting layer is sandwiched between two differently doped semiconductor layers, i.e., an n-type semiconductor and a p-type semiconductor. The light-emitting layer may be one of aluminum gallium indium phosphide (AlGaInP), indium gallium nitride (InGaN), and aluminum gallium arsenide (AlGaAs), and may have a conventional homostructure, a single heterostructure, a double heterostructure (DH), or a multiple quantum well (MQW) structure. The passivation layer 24 may be formed of Al₂O₃, silicon dioxide (SiO₂), silicon nitrides (SiNₓ), spin-on-glass (SOG) materials, silicone resins, benzocyclobutene (BCB) resins, epoxy resins, polyimides, or a combination of the above, by a conventional photolithography or etching process. For example, the passivation layer is deposited over the entire target surface by a conventional semiconductor deposition method and then coated with a photoresist layer, which is subsequently patterned by a pattern transfer technique (e.g., through exposure and developing) to define the to-be-exposed portions of the underlying semiconductor layer, with the patterned photoresist layer serving as mask. The extension contacts 23 are configured to connect the first semiconductor layer 251, the light-emitting layer 252, and the second semiconductor layer 253 to the electrical connection units 21, and may be any metal with high electrical conductivity. The protective layer 22 may be made of epoxy resins, polyimides, benzocyclobutane, liquid crystal polymers, or any other suitable dielectric materials. The electrical connection units 21 may be bumps or balls of any electrically conductive material, including metals, alloys, and composite metals, such as but not limited to tin, copper, and gold.

In this embodiment, the electrodes 3 may be any common electrically conductive material, including metals, alloys, and composite metals, such as but not limited to silver, copper, gold, aluminum, sodium, molybdenum, tungsten, zinc, nickel, iron, platinum, tin, lead, silver-copper alloys, cadmium-copper alloys, chromium-copper alloys, beryllium-copper alloys, zirconium-copper alloys, aluminum-magnesium-silicon alloys, aluminum-magnesium alloys, aluminum-magnesium-iron alloys, aluminum-zirconium alloys, iron-chromium-aluminum alloys, silicon carbide, and graphite.

In this embodiment, the cup structures 5 may be barrier walls commonly used in LED packages and be formed of a hardened transparent gel such as but not limited to a hardened silicone or resin.

In this embodiment, the fluorescent layers 6 refer to a transparent gel with fluorescent powder dispersed therein. The fluorescent layers 6 serve mainly to allow passage, and thereby change the color, of the light emitted by the CSP LED chips 2; to protect the CSP LED chips 2 and their electrical connection units 21; to reduce oxidation; and to thereby increase the service life of the CSP LED chips 2. Some examples of such transparent gels are phenolic resins, epoxy resins, silicones, polyurethane resins, unsaturated polyester resins, acrylic resins, polyolefins/thiols, and vinyl ether resins. Preferably, the fluorescent layers 6 are made of an epoxy resin, silicone, methyl silicone resin, phenyl silicone resin, methyl phenyl silicone resin, or modified silicone resin; the present invention has no limitation in the regard. While each fluorescent layer 6 in this embodiment is shown as covering the CSP LED chip 2 in the corresponding cup structure 5, the fluorescent layers 6 can be used to cover the CSP LED chips 2 in the absence of the cup structures 5 just as well; the present invention has no limitation in this regard.

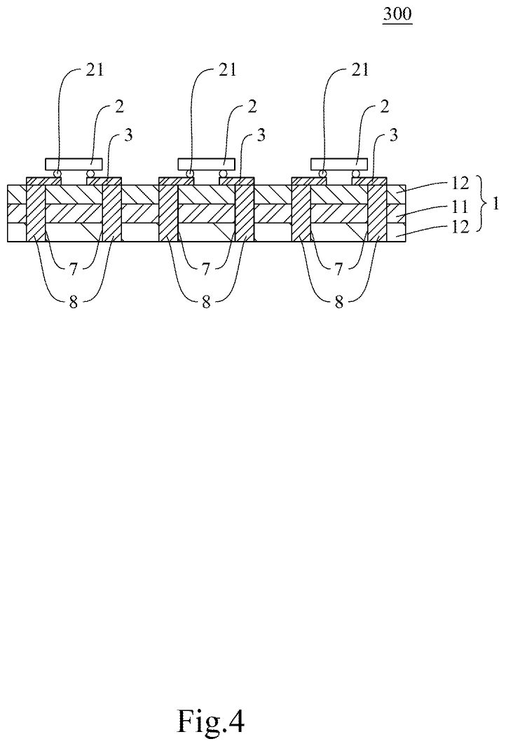

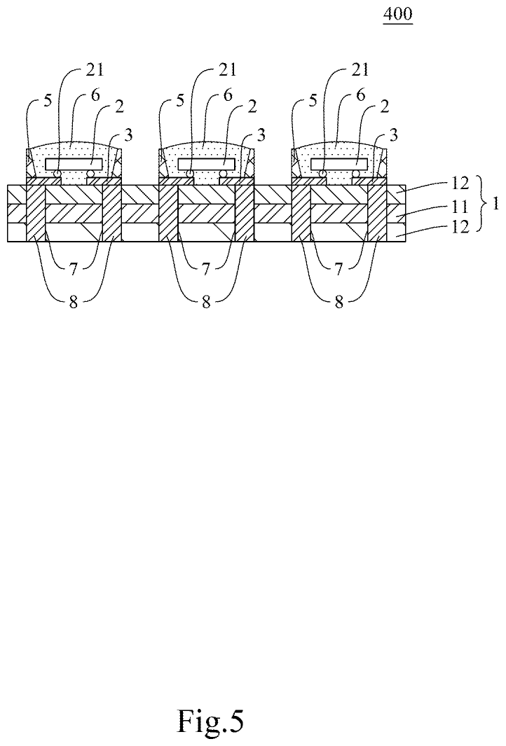

FIG. 4 and FIG. 5 show two LED structures according to the second embodiment of the present invention in sectional view.

In this embodiment, referring first to FIG. 4, the LED structure 300 includes a flexible substrate 1 and one or a plurality of CSP LED chips 2. The flexible substrate 1 includes a metal layer 11 as the core, and the metal layer 11 is coated with a ceramic insulating layer 12. The flexible substrate 1 is provided with a plurality of electrodes 3. The CSP LED chips 2 are provided on the flexible substrate 1, with the electrical connection units 21 of each CSP LED chip 2 electrically connected to the corresponding electrodes 3 on the flexible substrate 1 respectively. The flexible substrate 1 further has a plurality of through holes 7 and an electrical conduction unit 8 in each through hole 7.

The flexible substrate of the LED structure in this embodiment may further include at least one cup structure as needed. Referring to FIG. 5, each CSP LED chip 2 of the LED structure 400 is provided in a corresponding cup structure 5. In addition, the LED structure 400 includes a plurality of fluorescent layers 6, which are formed on the flexible substrate 1 to cover the CSP LED chips 2 respectively.

The LED structure in this embodiment has the same metal layer 11, ceramic insulating layer 12, electrodes 3, CSP LED chips 2, electrical connection units 21, and fluorescent layers 6 as the LED structure 100 in the first embodiment.

In this embodiment, the wall of each through hole 7 is provided with and covered by a ceramic insulating layer, which may be made of any common ceramic material as stated above, without limitation.

In this embodiment, the electrical conduction units 8 may be any common electrically conductive material, including metals, alloys, and composite metals, such as but not limited to silver, copper, gold, aluminum, sodium, molybdenum, tungsten, zinc, nickel, iron, platinum, tin, lead, silver-copper alloys, cadmium-copper alloys, chromium-copper alloys, beryllium-copper alloys, zirconium-copper alloys, aluminum-magnesium-silicon alloys, aluminum-magnesium alloys, aluminum-magnesium-iron alloys, aluminum-zirconium alloys, iron-chromium-aluminum alloys, silicon carbide, and graphite.

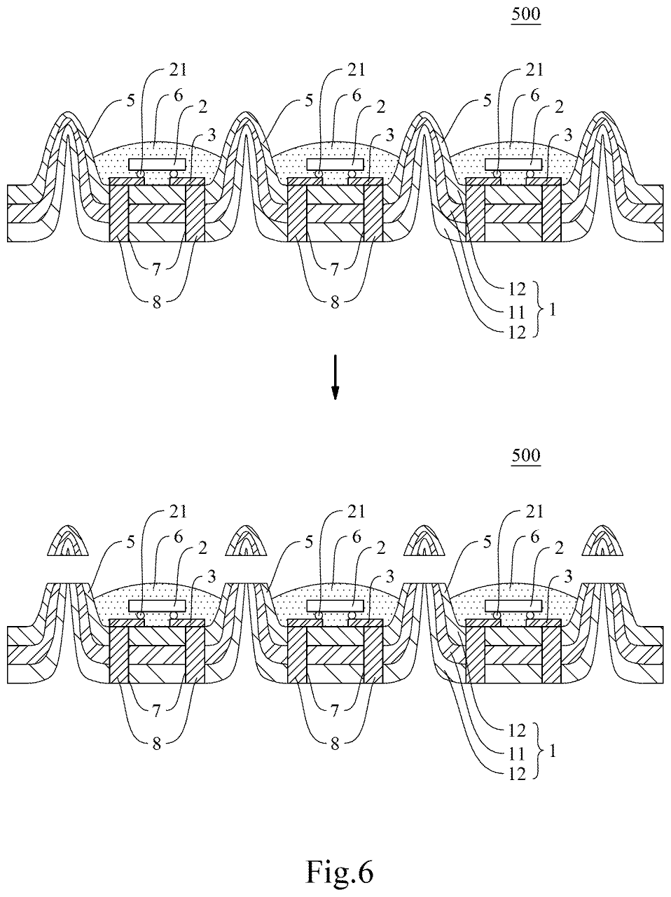

In this embodiment, the cup structures 5 may be the same as those in the first embodiment, i.e., being barrier walls commonly used in LED packages, and being formed of a hardened transparent gel such as but not limited to a hardened silicone or resin. Alternatively, referring to FIG. 6, the flexible substrate 1 of the LED structure 500 may be stamped to form closed, protruding structures as the cup structures 5. When the cup structures 5 are formed by stamping, the resulting LED structure can be directly cut into individual LEDs once encapsulated.

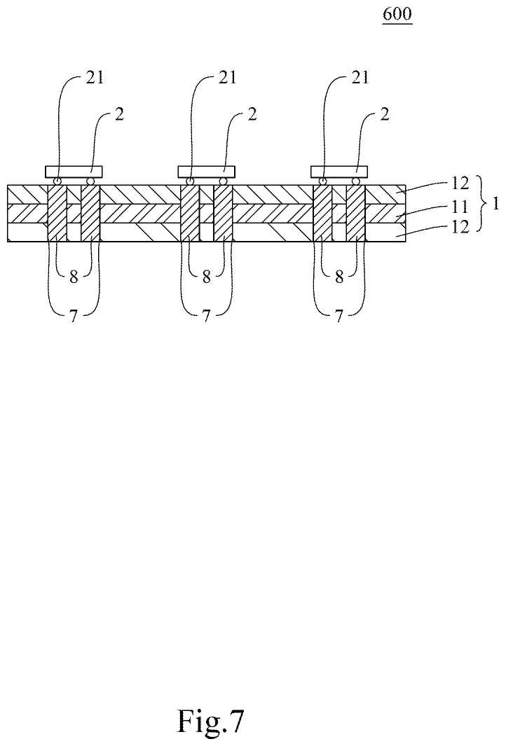

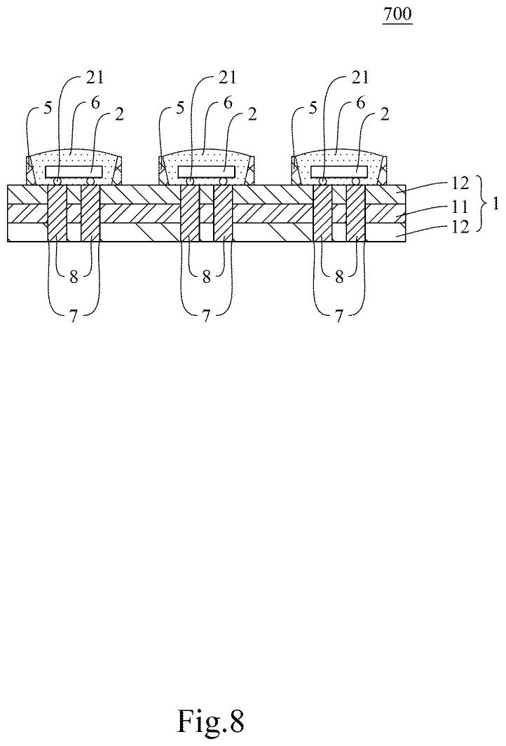

FIG. 7 and FIG. 8 show two LED structures according to the third embodiment of the present invention in sectional view.

In this embodiment, referring first to FIG. 7, the LED structure 600 includes a flexible substrate 1 and one or a plurality of CSP LED chips 2. The flexible substrate 1 includes a metal layer 11 as the core, and the metal layer 11 is coated with a ceramic insulating layer 12. The flexible substrate 1 has a plurality of through holes 7 and an electrical conduction unit 8 in each through hole 7. The CSP LED chips 2 are provided on the flexible substrate 1, and the electrical connection units 21 of each CSP LED chip 2 are electrically connected to the corresponding electrical conduction units 8 respectively.

The flexible substrate of the LED structure in this embodiment may further include at least one cup structure as needed. Referring to FIG. 8, each CSP LED chip 2 of the LED structure 700 is provided in a corresponding cup structure 5. In addition, the LED structure 700 includes a plurality of fluorescent layers 6, which are formed on the flexible substrate 1 to cover the CSP LED chips 2 respectively.

The LED structure in this embodiment has the same metal layer 11, ceramic insulating layer 12, CSP LED chips 2, electrical connection units 21, through holes 7, electrical conduction units 8, and fluorescent layers 6 as the LED structures 100 to 500 in the first and the second embodiments.

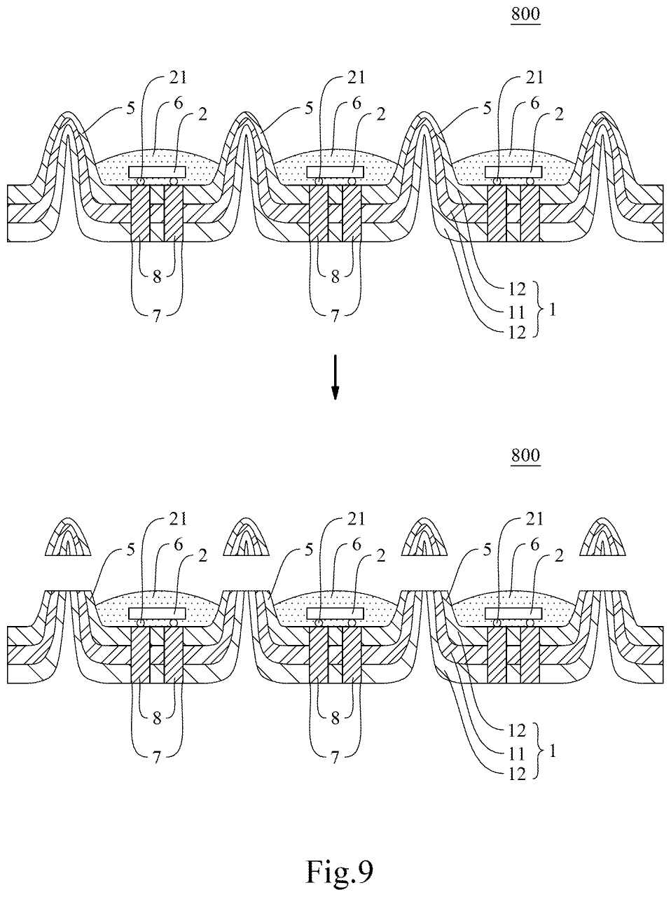

In this embodiment, the cup structures 5 may be the same as those in the first and the second embodiments, i.e., being barrier walls commonly used in LED packages, and being formed of a hardened transparent gel such as but not limited to a hardened silicone or resin. Alternatively, referring to FIG. 9, the flexible substrate 1 of the LED structure 800 may be stamped to form closed, protruding structures as the cup structures 5. When the cup structures 5 are formed by stamping, the resulting LED structure can be directly cut into individual LEDs once encapsulated.

As above, the LED structure of the present invention includes a flexible substrate and a plurality of CSP LED. The flexible substrate includes a core metal layer coated with a ceramic insulating layer. The CSP LED chip is provided on the flexible substrate. As the metal layer and the ceramic insulating layer have good heat dissipation properties, the resulting CSP LED is free of the drawbacks of its conventional counterparts, such as an overly concentrated heat flux and the incapability to dissipate heat evenly. Secondly, the flexible substrate of the LED structure of the present invention includes the core metal layer and the ceramic insulating layer coating and is therefore different from the entirely ceramic, and hence costlier, substrate of a conventional LED structure. In addition, the flexibility of the core metal layer provides better mechanical strength and allows variation of the exterior design of the LED structure disclosed herein, thereby increasing industrial applicability of the present invention. For example, the LED structure of the present invention can be bent for use as an LED filament. Thirdly, the CSP LED chip in the LED structure of the present invention can be disposed directly on the flexible substrate using surface mount technology (SMT) equipment, without requiring a vacuum clean room or a die bonding machine (both being expensive) as does an LED flip chip. The LED structure, therefore, features relatively low production cost.

With the advantageous features described above, an LED structure based on the present invention can be used in a lighting device, e.g., in an LED lightbulb or as an LED filament.

The above is the detailed description of the present invention. However, the above is merely the preferred embodiment of the present invention and cannot be the limitation to the implement scope of the present invention, which means the variation and modification according to the present invention may still fall into the scope of the invention.

What is claimed is:

1. A light-emitting diode (LED) structure, comprising:
a flexible substrate, wherein the flexible substrate comprises a metal layer as a core, the metal layer is coated with a ceramic insulating layer, and the flexible substrate is provided with a plurality of electrodes; and
at least one chip-scale package (CSP) LED chip (hereinafter referred to as the CSP LED chip for short), wherein the CSP LED chip is provided on the flexible substrate and comprises a plurality of electrical connection units each electrically connected to a corresponding one of the electrodes.

2. The LED structure of claim 1, wherein the flexible substrate has a plurality of through holes and an electrical conduction unit in each of the through hole.

3. The LED structure of claim 1, wherein the ceramic insulating layer has a thickness of 10 μm˜400 μm.

4. The LED structure of claim 2, wherein the ceramic insulating layer has a thickness of 10 μm˜400 μm.

5. The LED structure of claim 1, wherein the flexible substrate further includes at least one cup structure, and each of the CSP LED chip is provided in a corresponding one of the cup structure.

6. The LED structure of claim 2, wherein the flexible substrate further includes at least one cup structure, and each CSP LED chip is provided in a corresponding one of the cup structure.

7. The LED structure of claim 1, further comprising at least one fluorescent layer, wherein the fluorescent layer is formed on the flexible substrate and covers the CSP LED chip.

8. The LED structure of claim 2, further comprising at least one fluorescent layer, wherein the fluorescent layer is formed on the flexible substrate and covers the CSP LED chip.

9. A light-emitting diode (LED) structure, comprising:
a flexible substrate, wherein the flexible substrate comprises a metal layer as a core, the metal layer is coated with a ceramic insulating layer, and the flexible substrate is provided with a plurality of through holes and an electrical conduction unit in each of the through hole; and
at least one chip-scale package (CSP) LED chip (hereinafter referred to as the CSP LED chip for short), wherein the CSP LED chip is provided on the flexible substrate and comprises a plurality of electrical connection units each electrically connected to the corresponding electrical conduction units on the flexible substrate respectively.

10. The LED structure of claim 9, wherein the ceramic insulating layer has a thickness of 10 μm˜400 μm.

11. The LED structure of claim 9, wherein the flexible substrate further includes at least one cup structure, and each CSP LED chip of the LED structure is provided in a corresponding of the cup structure.

12. The LED structure of claim 9, further comprising at least one fluorescent layer, wherein the fluorescent layer is formed on the flexible substrate and covers the CSP LED chip.

13. The LED structure of claim 10, further comprising at least one fluorescent layer, wherein the fluorescent layer is formed on the flexible substrate and covers the CSP LED chip.

14. The LED structure of claim 11, further comprising at least one fluorescent layer, wherein the fluorescent layer is formed on the flexible substrate and covers the CSP LED chip.

15. A lighting device, comprising the LED structure of claim 1.
